(19) United States
(12) Patent Application Publication
(10) Pub. No.: US 2012/0313189 A1
(43) Pub. Date: Dec. 13, 2012

(54) METHOD OF PREVENTING STICTION OF MEMS DEVICES

(75) Inventors: Kegang HUANG, Fremont, CA (US); Martin LIM, San Mateo, CA (US); Xiang LI, Mountain View, CA (US)

(73) Assignee: INVENSENSE, INC., Sunnyvale, CA (US)

(21) Appl. No.: 13/489,380

(22) Filed: Jun. 5, 2012

Related U.S. Application Data
(60) Provisional application No. 61/494,766, filed on Jun. 8, 2011.

(51) Int. Cl. H01L 29/84; H01L 21/02

(52) U.S. Cl. 257/415; 438/50; 257/E29.324; 257/E21.002

(57) ABSTRACT

A method and apparatus are disclosed for reducing stiction in MEMS devices. The method comprises patterning a CMOS wafer to expose Titanium-Nitride (TiN) surface for a MEMS stop and patterning the TiN to form a plurality of stop pads on the top metal aluminum surface of the CMOS wafer. The method is applied for a moveable MEMS structure bonded to a CMOS wafer. The TiN surface and/or plurality of stop pads minimize stiction between the MEMS structure and the CMOS wafer. Further, the TiN film on top of aluminum electrode suppresses the formation of aluminum hillocks which effects the MEMS structure movement.

### CROSS-REFERENCE TO RELATED APPLICATION

This application claims the benefit of U.S. Provisional Patent Application No. 61/494,766, filed on Jun. 8, 2011, entitled “METHOD OF PREVENTING STICTION OF MEMS DEVICES,” which is incorporated herein by reference in its entirety.

### FIELD OF THE INVENTION

The present invention relates generally to the fabrication of Micro-Electro-Mechanical Systems (MEMS) devices, and more particularly to reducing the occurrence of stiction of and hillock formation in MEMS devices.

### BACKGROUND OF THE INVENTION

Fabrication platforms that integrate MEMS structures with electronics may utilize wafer-to-wafer bonding process to directly integrate pre-fabricated MEMS wafers to off-the-shelf CMOS wafers at the wafer level. The process simultaneously provides hermetic sealing of the plurality of devices with electric contacts during the wafer level bonding step.

Stiction is an undesirable situation which arises when surface adhesion forces are higher than the mechanical restoring force of a MEMS structure. Stiction is recognized to often occur in situations where two surfaces with areas in close proximity come in contact. The greater the contact area at both macroscopic and microscopic roughness levels, the risk of stiction increases. At the microscopic level, soft materials can deform, effectively increasing contact area. Surfaces can be unintentionally brought into contact by external environmental forces including vibration, shock and surface tension forces that are present during aqueous sacrificial release steps often used in micro-fabrication processes. Adherence of the two surfaces may occur causing the undesirable stiction.

Hillock formation on the aluminum surface in CMOS-MEMS devices can prevent proper device operation and is often associated with stress in the aluminum deposited layer. Elevated temperatures during processing cause metal grains to coalesce into larger grains creating displacements leading to hillock formation and protrusions from the surface. The use of chemical etchants leads to roughened features on the aluminum surface which may exacerbate the stress induced hillock formation. Although there is some sensitivity to the hillock formation in standard semiconductor devices, it is more of an issue for MEMS devices where an aluminum surface is a critical feature such as an electrode of a capacitive device on a MEMS structure.

As a result, it is highly desirable to reduce or eliminate stiction and hillock formations in such devices. Accordingly, what is desired is a system and method to address the above processing limitations.

### SUMMARY OF THE INVENTION

The present invention fulfills these needs and has been developed in response to the present state of the art, and in particular, in response to the problems and needs in the art that have not yet been fully solved by currently available technologies.

One embodiment of the present invention includes an apparatus comprising a MEMS structure and a substrate including a TiN surface opposing the MEMS structure.

Another embodiment of the present invention includes a method comprising providing a TiN contact surface on a substrate for a MEMS structure to prevent stiction between the MEMS structure and the substrate.

### BRIEF DESCRIPTION OF DRAWINGS

FIG. 1 illustrates an embodiment of a cross-section schematic of a moveable MEMS Si structure touching CMOS Al electrode surface representing a stuck condition presenting a stiction concern.

FIG. 2 illustrates an embodiment of a schematic side view of a CMOS wafer following passivation dielectric deposition.

FIG. 3 illustrates an embodiment of a schematic side view of a CMOS wafer following passivation dielectric pattern and etch.

FIG. 4 illustrates an embodiment of a schematic side view of a CMOS wafer following TiN pattern and etch.

FIG. 5 illustrates an embodiment of a schematic top view of a CMOS wafer following TiN pattern and etch.

FIG. 6 illustrates an embodiment of a cross-section schematic of a moveable MEMS Si structure that is not in contact with the TiN surface on top of CMOS Al electrode.

FIG. 7 illustrates an embodiment of a schematic top view of a moveable MEMS Si structure that is not in contact with the TiN surface on top of CMOS Al electrode.

FIG. 8 depicts an embodiment of a method of stiction reduction.

### DETAILED DESCRIPTION

The present invention relates generally to the fabrication of MEMS devices, and more particularly to reducing the occurrence of stiction and hillock formations in Micro-Electro-Mechanical Systems (MEMS) devices. The present invention provides solutions to reduce or eliminate stiction and hillock formations during MEMS processing.

The following description is presented to enable one of ordinary skill in the art to make and use the invention and is provided in the context of a patent application and its requirements. Various modifications to embodiments and the generic principles and features described herein will be readily apparent to those skilled in the art. Thus, the present invention is not intended to be limited to the embodiment shown but is to be accorded the widest scope consistent with the principles and features described herein.

As used herein, the terms stop pads and dimples are intended to be used interchangeably and reflect physical attributes which are created in the final steps of CMOS processing. In the described embodiments, the surface materials of stop pads and a stop surface are understood to be Titanium Nitride (TiN) film or an equivalent. In the described embodiments, TiN film is provided on an aluminum (Al) electrode to suppress Al hillock growth. In the described embodiments, the MEMS device comprises a MEMS structure and integrated electronics. In the described embodiment, silicon dioxide (SiO₂) and silicon oxide (SiO) are used interchangeably to refer to silicon dioxide.

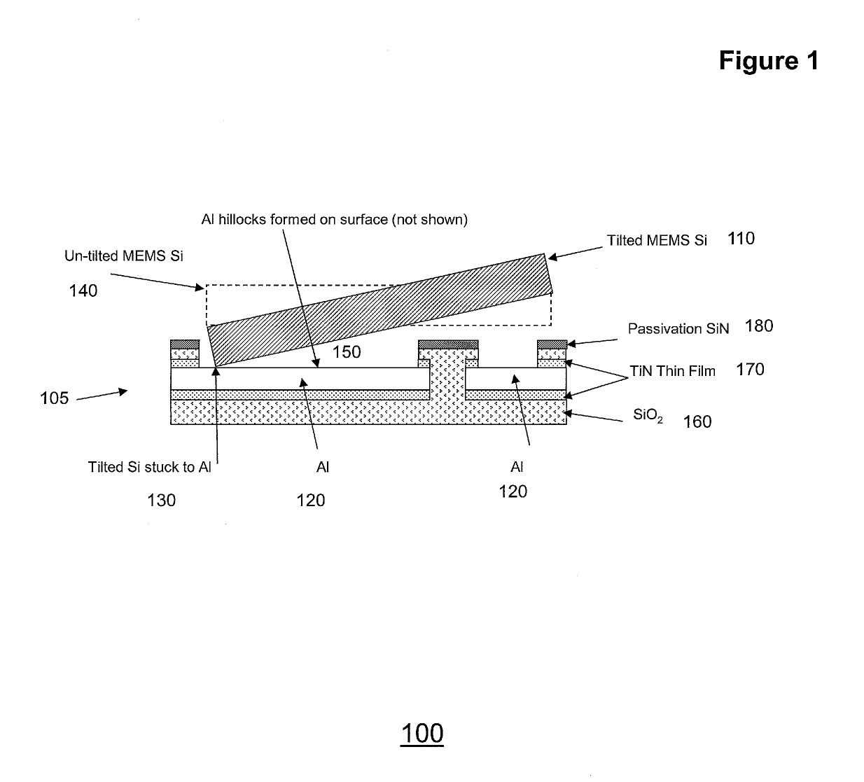

FIG. 1 illustrates an embodiment of a cross-section schematic 100 of a moveable MEMS Si structure 110 in contact with CMOS Al electrode surface 120 representing a stuck condition at 130 presenting a stiction concern. CMOS wafer 105 includes a layer of silicon oxide 160, an aluminum layer 120, thin TiN layers 170, and a layer of silicon nitride 180. The MEMS structure 110 can move, tilt and rotate from an untilted position at 140 to touch an aluminum electrode surface 120 of the CMOS wafer 105 at 130. Due to the material properties of aluminum (Al) and silicon (Si), during contact between the MEMS Si structure and the surface of aluminum layer 120 at 130, the aluminum layer 120 may deform forming dents on the aluminum 120 surface. The contact area between the aluminum 120 surface and the MEMS Si structure 110 will therefore increase due to the dent deformation in addition to the smoothing of the surface roughness. The additional contact area may therefore cause the MEMS silicon structure 110 to remain in contact with the aluminum 120 surface and cause an undesirable stuck or stiction condition. Similarly, hillocks may also form on the aluminum surface 120. The TiN thin film layers are located at 170 and a passivation layer is located at 180.

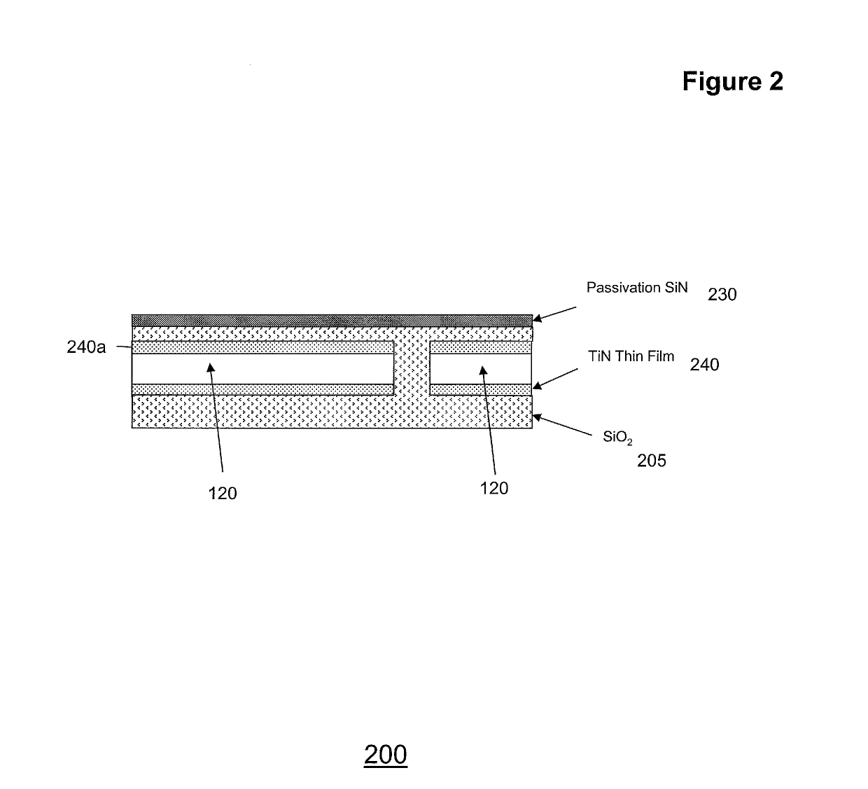

FIGS. 2 through 7 illustrate embodiments of the schematic side views of CMOS process flow to form TiN surfaces, pads or dimples on top of CMOS top metal Al. The TiN film is patterned in certain predesigned areas for the MEMS silicon structure to land or contact during movement but without stiction or with a significantly reduced stiction.

FIG. 2 illustrates a schematic side view of a CMOS wafer 200 following passivation dielectric deposition. From FIG. 2, a schematic side view of CMOS wafer 200 with top metal aluminum layer 120 on a Silicon oxide layer 205 with passivation films of silicon oxide (SiO) and silicon nitride (SiN) 230. A thin TiN film, typically 20 nm is normally deposited on top (240a) and bottom (240) of the aluminum layer 120 during standard CMOS processing. In an embodiment, aluminum layer 120 can be an electrode or a wafer bonding pad. The top TiN layer 240a serves as an antireflection coating (ARC) for patterning the aluminum layer 120. In an embodiment, the TiN film thickness can be increased (20-2000 nm) to provide a thicker and more robust TiN layer to serve as a non-stiction contact layer 240a.

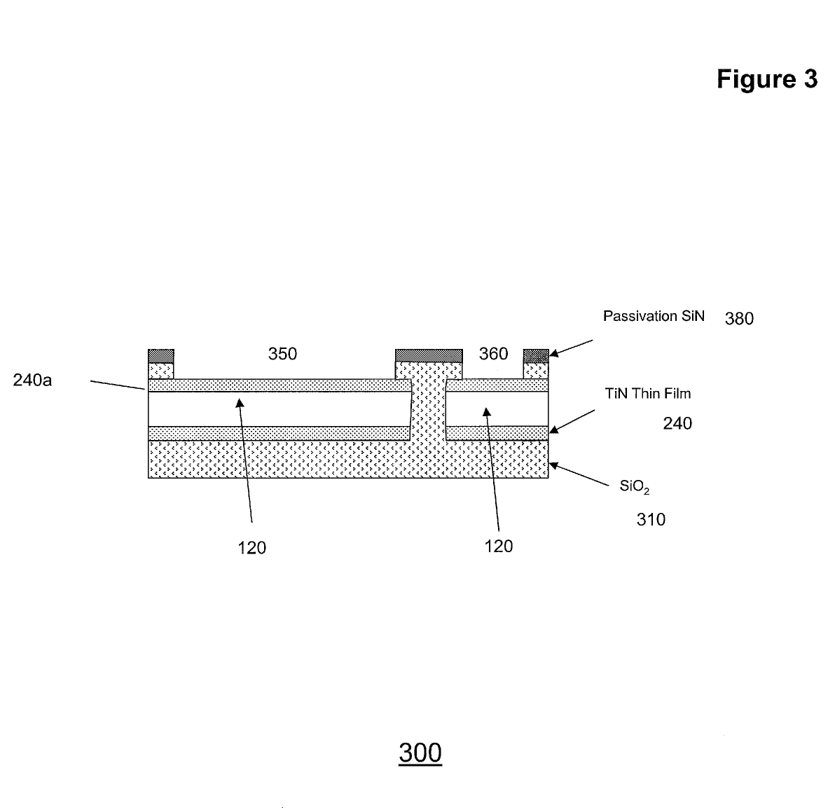

FIG. 3 illustrates an embodiment of a schematic side view of a CMOS wafer 300 following passivation pattern and etch. FIG. 3 presents the cross-sectional view of the CMOS wafer 300 illustrating the selective removing of the passivation layers, of SiN and SiO at 350 and 360, as part of the CMOS pad removal module. Silicon oxide 310 remains after removing a portion of the SiO to expose the TiN layer 240a. For the present invention, the traditional TiN removal is eliminated from the CMOS pad etch module as it is desirable to retain the TiN layer 240a. The TiN layer 240a deposited earlier on top of the aluminum layer 120 during standard CMOS processing remains with passivation layer 380 having resulting voids, 350 and 360.

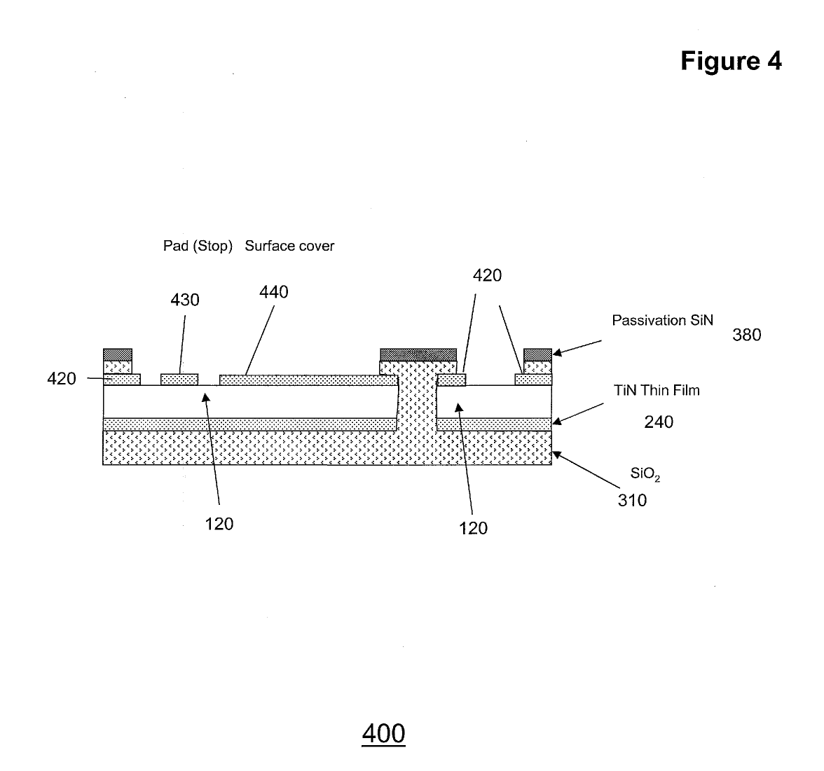

FIG. 4 illustrates an embodiment of a schematic side view of a CMOS wafer 400 following TiN pattern and etch. FIG. 4 illustrates the patterning of the TiN layer 420 to selectively retain TiN contact areas or pads 430, surface cover 440 and under passivation TiN 420, for example. The pad stop 430 area is typically defined to limit the contact area to prevent or significantly reduce stiction. The conductive characteristic of TiN prevents charging which can further exacerbate stiction occurrence or to a lesser degree compromise the performance of the MEMS silicon structure by degrading the electric field between the charged surface and the silicon structure. TiN is harder than aluminum and will deform less at the surface. The lower deformation corresponds to less contact area increase and hence exhibits a lower stiction characteristic. Therefore, it will be appreciated by those skilled in the art that the present invention selection of TiN is more attractive as a contact layer than insulating materials such as SiO and SiN where a conductive material is desired for mechanical contact. Aluminum layer 120 remains and the passivation layer is located at 380.

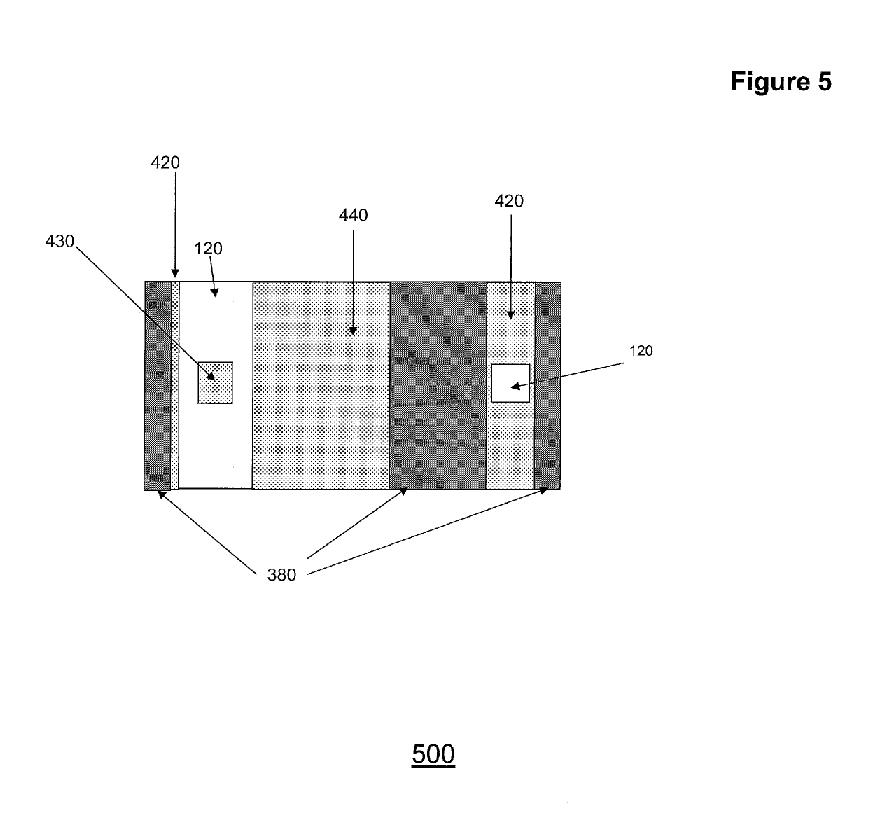

FIG. 5 illustrates an embodiment of a schematic top view of a CMOS wafer 500 following TiN pattern and etch (i.e., a further perspective view of the side view shown in FIG. 4) before CMOS wafer bonding to MEMS wafers. Other TiN coverage areas such as hillock suppressing pad 440 may be retained to suppress aluminum hillock formation which can alter the effective electric field between the silicon MEMS structure and the aluminum layer 120. In the extreme case the hillock formation can cause huge surface asperities that may compromise the gap clearance between the silicon structure and the aluminum layer 120. Furthermore these asperities or large protrusions are additional stiction areas and can be areas where aluminum is inadvertently transferred from the CMOS to MEMS surface during incidental contact. A passivation layer is located at 380 and a TiN contact pad is located at 430.

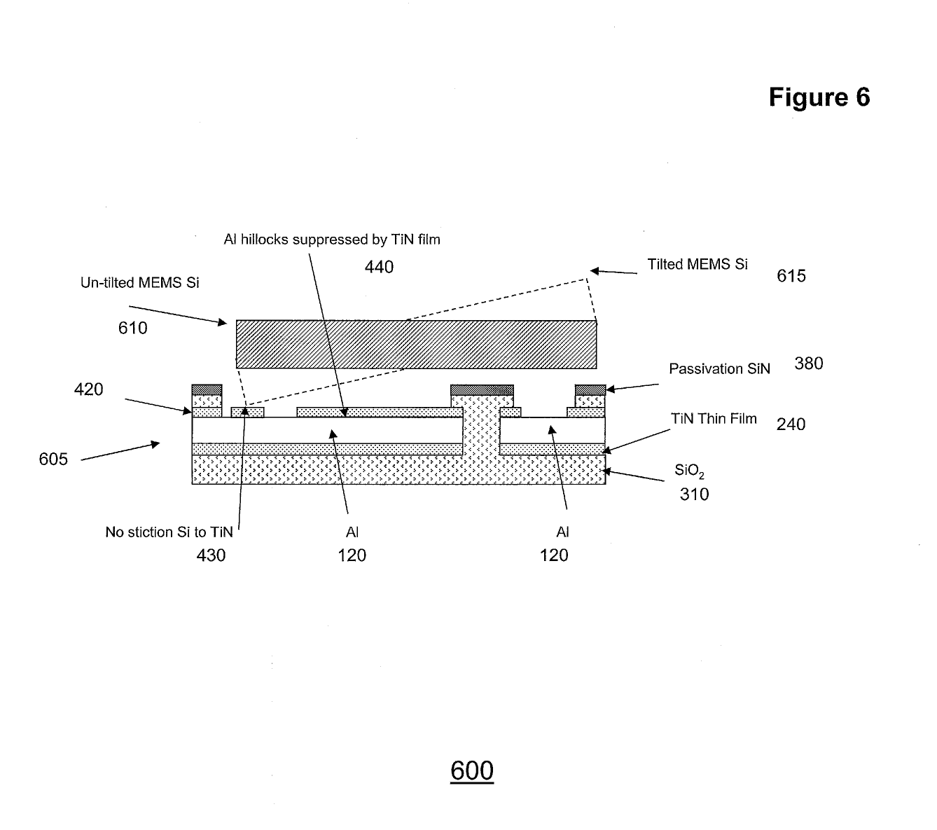

FIG. 6 illustrates an embodiment of a cross-section schematic 600 having a moveable MEMS Si structure 610 and a CMOS wafer 605. MEMS structure 610 represents the desired position. A possible titled position of MEMS structure 610 is shown as 615 where the MEMS Si structure 610 is in contact with the TiN surface 430 on top of aluminum layer 120. The resulting benefit from the present invention in accordance with one or more embodiments, is that the contact is temporary and the MEMS structure returns to its original desired position 610. In addition, an area where the TiN surface is used to suppress hillock formation is shown at 440. Passivation layer is located at 380.

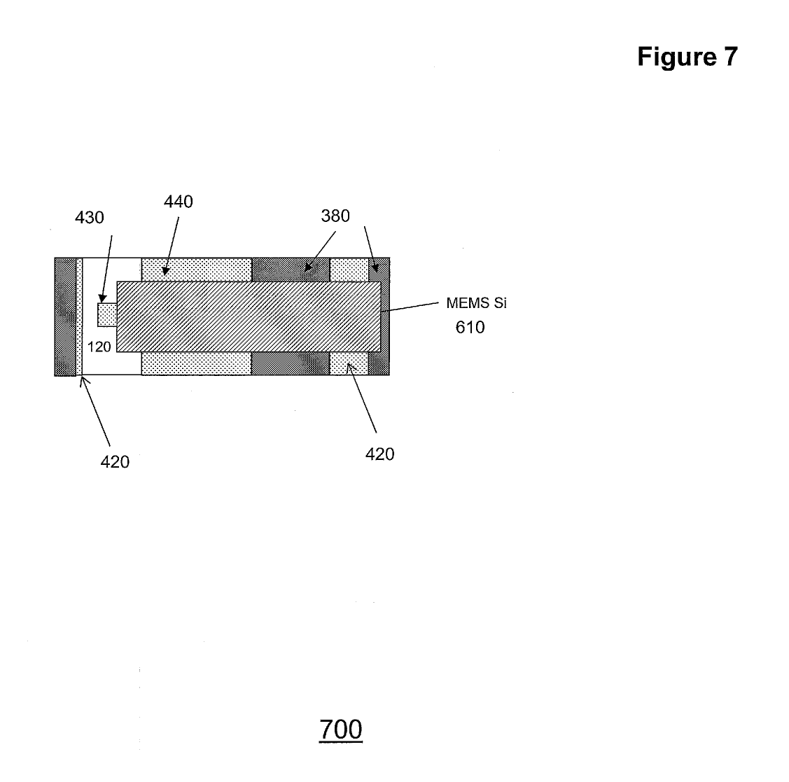

FIG. 7 illustrates an embodiment of a schematic top view 700 of a moveable MEMS Si structure 610 that is not in contact with the TiN surface 430 on top of aluminum layer 120 (i.e., a further perspective view of the side view shown in FIG. 6). A passivation layer is located at 380.

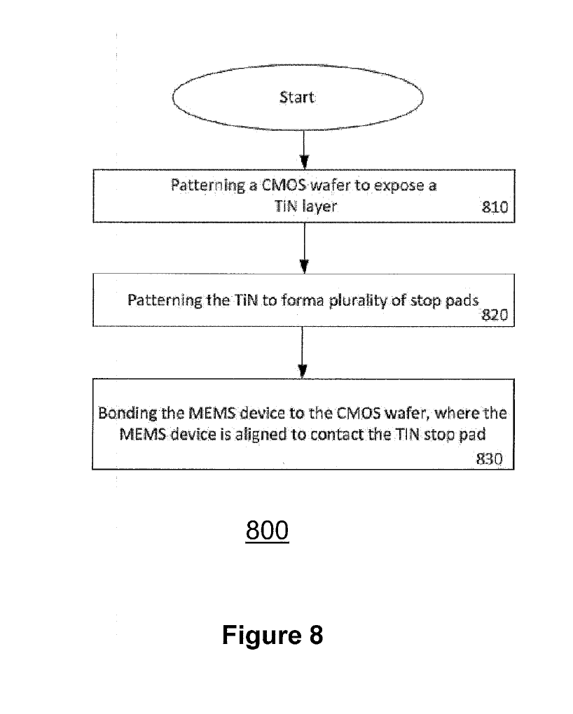

FIG. 8 depicts an embodiment of a method 800 of reducing stiction in a micro-electromechanical system (MEMS) device. The method 800 includes patterning a CMOS wafer to expose a TiN surface layer, via step 810, patterning the TiN layer to form a plurality of stop pads, via step 820, and bonding a moveable MEMS structure to the CMOS wafer, where the MEMS structure is aligned to contact the TIN stop pad, via step 830. The MEMS stop pad is situated proximate to the aluminum layer to include at least one MEMS stop pad, on the wafer. The described embodiments use TiN as a contact surface for a MEMS Si structure stop. TiN is a harder material than Al and is subject to lesser likelihood of deformation. TiN is a conductive material and is better situated than dielectrics while being devoid of the relevant charging issues. Si—TiN contact has a lower stiction force than Si—Al contact. TiN is used in standard CMOS processing and may not require any additional steps. TiN on top of Al electrode surface suppresses and may even reduce the formation of large Al hillocks. The Al hillocks may have uncertain effects on MEMS device quality and performance.

Although the present invention has been described in accordance with the embodiments shown, one of ordinary skill in the art will readily recognize that there could be variations to the embodiments and those variations would be within the spirit and scope of the present invention, such as the inclusion of circuits, electronic devices, control systems, and other electronic and processing equipment. Accordingly, many modifications may be made by one of ordinary skill in the art without departing from the spirit and scope of the appended claims. Many other embodiments of the present invention are also envisioned. Any theory, mechanism of operation, proof, or finding stated herein is meant to further enhance understanding of the present invention and is not intended to make the present invention in any way dependent upon such theory, mechanism of operation, proof, or finding.

What is claimed is:

1. An apparatus comprising:
a Micro-Electro-Mechanical Systems (MEMS) structure; and
a substrate including a Titanium-Nitride (TiN) surface opposing the MEMS structure.

2. The apparatus of claim 1, wherein the TiN surface prevents stiction between the MEMS structure and the TiN surface.

3. The apparatus of claim 1, wherein the TiN surface prevents hillock formation on the substrate.

4. The apparatus of claim 1, where in the substrate is a CMOS wafer.

5. The apparatus of claim 1, where in the MEMS structure is silicon.

6. The apparatus of claim 5, where the silicon is single crystal silicon.

7. The apparatus of claim 1, where in the substrate includes an electronic circuit.

8. The apparatus of claim 1, where the TiN surface is deposited on a top metal layer of the CMOS wafer.

9. The apparatus of claim 8, where in the top metal layer is aluminum.

10. The apparatus of claim 9, where in a portion of the aluminum is electrically connected to an electronic circuit.

11. The apparatus of claim 1 wherein the TiN surface is patterned to form one or more electrically conductive areas.

12. A method comprising:
providing a Titanium-Nitride (TiN) surface on a substrate for a Micro-Electro-Mechanical Systems (MEMS) structure to prevent stiction between the MEMS structure and the substrate.

13. A method for reducing stiction of a micro-electromechanical system (MEMS) device, comprising the steps of:
patterning a CMOS wafer to expose a Titanium-Nitride (TiN) surface to include at least one MEMS stop pad, on the wafer; and
bonding the MEMS structure to the CMOS wafer.

14. The method of claim 13, wherein the step of patterning further exposes a plurality of TiN stop pads on the CMOS wafer, wherein the plurality of TiN stop pads minimizes stiction between the MEMS structure and the CMOS wafer.

15. The method of claim 14, wherein the TiN layer further significantly reduces the formation of hillocks on a substrate.

16. The method of claim 15, wherein the substrate is the CMOS wafer.

17. The method of claim 16, wherein the MEMS device is a MEMS structure comprised at least in part of silicon.

18. The method of claim 17, wherein the MEMS device further includes an electronic circuit.

19. The method of claim 18, further comprising the step of enabling the electronic circuit for operation wherein at least a portion of the aluminum layer of the wafer is in electrical communication with an electronic circuit.

20. The method of claim 13, wherein the step of patterning further comprises forming a plurality of electrically conductive areas by exposing a plurality of TiN surface areas.

21. The method of claim 13, further comprising an aluminum layer next to the TiN layer.
